(19) United States
(12) Patent Application Publication
(10) Pub. No.: US 2023/0402457 A1
(43) Pub. Date: Dec. 14, 2023

(54) TRANSISTOR STRUCTURE AND METHOD FOR FABRICATING THE SAME

(71) Applicant: Invention And Collaboration Laboratory Pte. Ltd., Singapore (SG)

(72) Inventors: Chao-Chun LU, Hsinchu (TW); Ming-Hong KUO, Hsinchu (TW); Chun-Nan LU, Hsinchu (TW)

(73) Assignee: Invention And Collaboration Laboratory Pte. Ltd., Singapore (SG)

(21) Appl. No.: 18/208,388

(22) Filed: Jun. 12, 2023

Related U.S. Application Data
(60) Provisional application No. 63/351,846, filed on Jun. 14, 2022.
(60) Provisional application No. 63/351,849, filed on Jun. 14, 2022.

(51) Int. Cl. H01L 27/092; H01L 29/06; H01L 29/78; H01L 29/423; H01L 21/8238; H01L 29/66

(52) U.S. Cl. CPC H01L 27/092; H01L 29/0653; H01L 29/7833; H01L 29/42376; H01L 21/823814; H01L 21/82385; H01L 21/823878; H01L 29/66492

(57) ABSTRACT

A transistor structure includes a semiconductor substrate, a gate region a spacer, a first trench, a first isolation region and a conductive region. The semiconductor substrate has an active region which has a semiconductor surface. The gate region has a first conductive portion over the semiconductor surface of the semiconductor substrate in the active region and a second conductive portion over the first conductive portion. The spacer covers a sidewall of the gate region. The first trench is formed below the semiconductor surface of the semiconductor substrate in the active region. The first isolation region is in the first trench. The conductive region is positioned on the first isolating region. Wherein a lateral length of the first conductive portion is greater than that of the second conductive portion.

This application claims the benefit of U.S. provisional applications Ser. No. 63/351,846 and Ser. No. 63/351,849, both filed Jun. 14, 2022, the subject matter of which is incorporated herein by reference.

### BACKGROUND OF THE DISCLOSURE

### Field of the Disclosure

The disclosure relates in general to a semiconductor structure and the method for fabricating the same, and more particularly to a transistor structure and the method for fabricating the same.

### Description of the Related Art

The success of low power integrated circuits industry is primarily due to the complementary metal oxide semiconductor (CMOS) technology, wherein the key role of integrated circuits is the MOSFET (metal-oxide-semiconductor field-effect transistor). Although advanced technology nodes (such as 3-10 nm) for Fin structure transistors are frequently used in high performance computing applications (such as Artificial Intelligence AI, CPU, GPU, etc.), the mature technology nodes (such as 12-30 nm) for planar MOSFET are still popular in many IC applications, such as, power management IC, DRAM, and MCU chip.

FIG. 1 shows a state-of-the-art planar CMOS device 10 which includes a PMOS transistor 11 and a NMOS transistor 12. The transistor gate structure 11G/12G using some conductive material (like metal, polysilicon or silicide, etc.) over an insulator (such as oxide, oxide/nitride or some high-k dielectric, etc.) is formed on top of a silicon surface, and the CMOS device 10 are isolated from those of other transistors (not shown) by using insulation materials 103 (e.g. oxide or oxide/nitride or other dielectrics). For an NMOS transistor 12, there are source and drain regions 12S/D which are formed by an ion-implantation plus thermal annealing technique to implant n-type dopants into a p-type substrate 100 (or a p-well) which thus results in two separated n+/p junction areas 104. For the PMOS transistor 11 both source and drain regions 11S/D are formed by ion-implanting p-type dopants into an n-well which thus results in two p+/n junction areas 104.

However, during the previously mentioned thermal annealing process, the implanted n-type or p-type dopants will unavoidably diffuse into different directions and enlarge the area of the source and drain regions. The larger the area of the source and drain regions due to the thermal annealing processes, the shorter of the effective channel length between the source and drain regions, and such reduced effective channel length (Leff) will incur short channel effect (SCE). An MOS transistor could be considered to be shorted when the Leff is comparable to the source/drain junction depletion width. When the Leff is further reduced, the drain current finally cannot be turned off and the gate has no control over the charge. The so-called punch-through effect poses a severe problem for miniaturized devices. Therefore, to reduce the impact of SCE, it is common to reserve longer gate length to accommodate the diffusion of n-type or p-type dopants due to thermal annealing. Using technology node of 25 nm (Lamda or A) as an example, the reserved gate length would be 60 nm to 100 nm. Thus, the size of the transistor could not be proportionally shrunk.

Other problems are introduced or getting worse in current planar MOSFETs made by mature technology nodes of 12 nm to 30 nm: (1) All junction leakages resulted by junction formation processes, such as forming lightly-doped drain (LDD) structure into the substrate/well regions, forming n+ source/drain structures into p-substrate and forming p+ source/drain structures into n-well, are getting worse to control, since leakage currents occur through both perimeter and bottom areas where extra damages like vacant traps for holes and electrons are harder to be reconciled due to lattice imperfections which have been created by ion-implantation; (2) In addition, since the ion-implantation to form the LDD structure (or the n+/p junction or the p+/n junction) works like bombardments in order to insert ions from the top of a silicon surface straight down to the substrate, it is hard to create uniform material interfaces with lower defects from the source and drain regions to the channel and the substrate-body regions since the dopant concentrations are non-uniformly distributed vertically from the top surface with higher doping concentrations down to the junction regions with lower doping concentrations; (3) It's getting harder to align the LDD junction edge to the edge of gate structure in a perfect position by only using the conventional self-alignment method of using gate, spacer and ion-implantation formation. In addition, the thermal annealing process for removing the ion-implantation damages must count on high temperature processing techniques such as rapid thermal annealing method by using various energy sources or other thermal processes. One problem thus created is that a gate-induced drain lowering (GIDL) leakage current is badly induced due to a gated diode structure formed in the gate-to-source/drain regions and hard to be controlled regardless the fact that it should be minimized to reduce leakage currents; the other problem as created is that the effective channel length is difficult to be controlled and so the short channel effect is hardly minimized. (4) As the dimensions of the transistors are continuously scaled down, manufacture parameter fluctuations cause undesirable result and impact on the circuit performance, for example, line edge roughness (LER), random dopant fluctuations (RDFs) and poly grain granularity (PGG), will unavoidably incur the variation of gate length (or the effective channel length) and then the threshold voltage V T variation, as shown in FIG. 1.

Therefore, there is a need to provide an advanced transistor structure and the processing method therefor to overcome the drawbacks of the prior art.

### SUMMARY OF THE DISCLOSURE

This invention discloses several new concepts of realizing a novel transistor structure, such as a planar transistor, which greatly improves or even solved most of the problems as stated above, such as minimizing current leakages, increasing channel-conduction performance and control, optimizing functions of source and drain regions such as making better their conductance to metal interconnections and their closest physical intact to the channel region with a seamless orderly crystalline lattice matchup.

One aspect of the present disclosure is to provide a transistor structure, wherein the transistor structure includes a semiconductor substrate, a gate region, a spacer, a trench, an isolation region and a conductive region. The semiconductor substrate has an active region which has a semiconductor surface. The gate region has a first conductive portion over the semiconductor surface of the semiconductor substrate in the active region and a second conductive portion over the first conductive portion. The spacer covers a sidewall of the gate region. The trench is formed below the semiconductor surface of the semiconductor substrate in the active region. The isolation region is in the trench. The conductive region is positioned on the isolating region. Wherein a lateral length of the first conductive portion is greater than that of the second conductive portion.

In one embodiment of the present disclosure, the isolation region includes a vertical layer and a bottom layer; an edge of the vertical layer is underneath the spacer; and a gap between the edge of the vertical layer and an edge of the first conductive portion of the gate region is less than 3 nm.

In one embodiment of the present disclosure, the conductive region is independent from the semiconductor substrate.

In one embodiment of the present disclosure, the transistor structure is a planar NMOS transistor, the conductive region includes an N type LDD region and an N type heavily doped region contacting with the N type LDD region.

In one embodiment of the present disclosure, a top surface of the N type LDD region is fully covered by the spacer.

In one embodiment of the present disclosure, the isolation region further includes a filling dielectric region on the bottom layer, and a top surface of the vertical layer is aligned or substantially aligned with that of the filling dielectric region.

In one embodiment of the present disclosure, the vertical layer and the bottom layer of the first isolation region are made of thermal oxide, and the filling dielectric region is made of a spin-on-dopant (SOD) layer.

In one embodiment of the present disclosure, the N type LDD region is on the vertical layer and the N type heavily doped region is on the filling dielectric region.

In one embodiment of the present disclosure, a vertical thickness of the N type LDD region is less than 20 nm, and a lateral width of the N type LDD region is around 20 nm.

In one embodiment of the present disclosure, the transistor structure further includes a shallow trench isolation (STI) region below the semiconductor surface of the semiconductor substrate in the active region and an extending dielectric layer above the STI region, wherein the extending dielectric layer includes a vertical portion, and a top surface of the vertical portion is higher than the semiconductor surface of the semiconductor substrate in the active region.

In one embodiment of the present disclosure, the conductive region is confined by the vertical portion of the extending dielectric layer.

Another aspect of the present disclosure is to provide a transistor structure, wherein the transistor structure includes a semiconductor substrate, a first trench, a second trench, a first isolation region, a second isolation region, a gate region, a channel region, a drain region and a source region. The semiconductor substrate has an active region which has a semiconductor surface. The first trench and a second trench are both formed below the semiconductor surface. The first isolation region is in the first trench. The second isolation region is in the second trench. The gate region has a first conductive portion over the semiconductor surface of the semiconductor substrate in the active region and a second conductive portion over the first conductive portion. The channel region is under the gate region. The drain region is on the first isolation region. The source region is on the second isolation region. Wherein a lateral length of the first conductive portion is different from that of the second conductive portion, and a distance between an edge of the first isolation region and an edge of the second isolation region is greater than the lateral length of the first conductive portion.

In one embodiment of the present disclosure, the distance between the edge of the first isolation region and the edge of the second isolation region is greater than the length of the lateral length of the first conductive portion around 4 nm.

In one embodiment of the present disclosure, the transistor structure further includes a STI region below the semiconductor surface of the semiconductor substrate in the active region and an extending dielectric layer above the STI region, wherein the extending dielectric layer includes a vertical portion surrounding the active region, and a top surface of the vertical portion is higher than the semiconductor surface of the semiconductor substrate in the active region.

In one embodiment of the present disclosure, the drain region and the source region are confined by the vertical portion of the extending dielectric layer.

Yet another aspect of the present disclosure is to provide a transistor structure, wherein the transistor structure includes a semiconductor substrate and a gate region. The semiconductor substrate has an active region which has a semiconductor surface. The gate region has a first conductive portion over the semiconductor surface of the semiconductor substrate in the active region and a second conductive portion over the first conductive portion. Wherein a lateral length of the first conductive portion is greater than that of the second conductive portion.

In one embodiment of the present disclosure, the transistor structure further includes a first spacer and a second spacer, wherein the second spacer contacts sidewalls of the second conductive portion rather than the first conductive portion, and the first spacer contacts sidewalls of the first conductive portion.

In one embodiment of the present disclosure, an edge of the first conductive portion is aligned or substantially aligned with an edge of the second spacer.

In one embodiment of the present disclosure, the second conductive portion includes a metal containing material, and the first conductive portion is made of a first semiconductor material which is different from the metal containing material.

In one embodiment of the present disclosure, the metal containing material of the second conductive portion is surrounded by the second spacer.

In one embodiment of the present disclosure, the second spacer is made of SiN.

In one embodiment of the present disclosure, the transistor structure further includes a gate dielectric layer under the first conductive portion, and a lateral length of the gate dielectric layer is greater than that of the second conductive portion.

In one embodiment of the present disclosure, a length of the gate region is immune from a gate line edge roughness.

In one embodiment of the present disclosure, a vertical thickness of the first conductive portion is 10 nm to 15 nm.

In one embodiment of the present disclosure, the transistor structure further includes a first spacer and a second spacer, wherein the second spacer contacts sidewalls of the second conductive portion and is positioned on a top surface of the first conductive portion.

### BRIEF DESCRIPTION OF THE DRAWINGS

The above and other aspects of the disclosure will become better understood with regard to the following detailed description of the preferred but non-limiting embodiment(s). The following description is made with reference to the accompanying drawings:

FIG. 1 is a cross-sectional view illustrating a planar CMOS device which includes a PMOS transistor and a NMOS transistor according to the prior art;

FIG. 2 is a flow chart illustrating the step for forming a transistor structure according to one embodiment of the present disclosure;

FIG. 2A is a cross-sectional view illustrating a semiconductor substrate having an active region defined on a semiconductor surface of the semiconductor substrate by a plurality of STI regions, according to one embodiment of the present disclosure;

FIG. 2B is a cross-sectional view illustrating the partial structure (for forming an NMOS transistor) after a silicon oxide layer, a SiN layer and a SOD layer are sequentially deposited on the semiconductor surface, and the SOD layer is etched back, according to one embodiment of the present disclosure;

FIG. 2C is a cross-sectional view illustrating the partial structure (for forming the NMOS transistor) after portions of the silicon oxide layer and the SiN layer are etched to expose the active region, according to one embodiment of the present disclosure;

FIG. 2D is a cross-sectional view illustrating the partial structure (for forming the NMOS transistor) after a gate dielectric layer, a gate semiconductor layer, a barrier layer, a metal layer, a SiN cap layer and an oxide cap layer are formed to cover the surface of the semiconductor substrate in the active region, according to one embodiment of the present disclosure;

FIG. 2E is a cross-sectional view illustrating the partial structure (for forming the NMOS transistor) after an upper conductive portion of a gate region is formed on the semiconductor surface of the semiconductor substrate in the active region, according to one embodiment of the present disclosure;

FIG. 2F is a cross-sectional view illustrating the partial structure (for forming the NMOS transistor) after an inner spacer contacting the sidewall of the upper conductive portion is formed, according to one embodiment of the present disclosure;

FIG. 2G is a cross-sectional view illustrating the partial structure (for forming the NMOS transistor) after a lower conductive portion of the gate region is formed on the gate dielectric layer and beneath the upper conductive portion, according to one embodiment of the present of disclosure;

FIG. 2H is a cross-sectional view illustrating the partial structure (for forming the NMOS transistor) after a dielectric layer for forming an outer spacer is formed, according to one embodiment of the present disclosure;

FIG. 2I is a cross-sectional view illustrating the partial structure (for forming the NMOS transistor) after the outer spacer is formed according to one embodiment of the present disclosure;

FIG. 2J is a cross-sectional view illustrating the partial structure (for forming the NMOS transistor) after a plurality of trenches are formed in the semiconductor substrate below the semiconductor surface of the semiconductor substrate in the active region, according to one embodiment of the present disclosure;

FIG. 2K is a cross-sectional view illustrating the partial structure (for forming the NMOS transistor) after a thermal oxide layer is formed on the bottoms and sidewalls of the trenches, according to one embodiment of the present disclosure;

FIG. 2L is a cross-sectional view illustrating the partial structure (for forming the NMOS transistor) after a plurality of isolation regions are formed, according to one embodiment of the present disclosure;

FIG. 2M is a cross-sectional view illustrating the partial structure (for forming the NMOS transistor) after a plurality of undercuts are formed below the gate region to partially expose the semiconductor substrate, according to one embodiment of the present disclosure;

FIG. 2N is a cross-sectional view illustrating the partial structure (for forming the NMOS transistor) after a plurality of first selective growth portions are formed in the undercuts, according to one embodiment of the present disclosure;

FIG. 2O is a cross-sectional view illustrating the partial structure (for forming the NMOS transistor) after a plurality of conductive regions are formed on the isolation regions, according to one embodiment of the present disclosure; and

FIG. 2P is a cross-sectional view illustrating a transistor structure, according to one embodiment of the present disclosure.

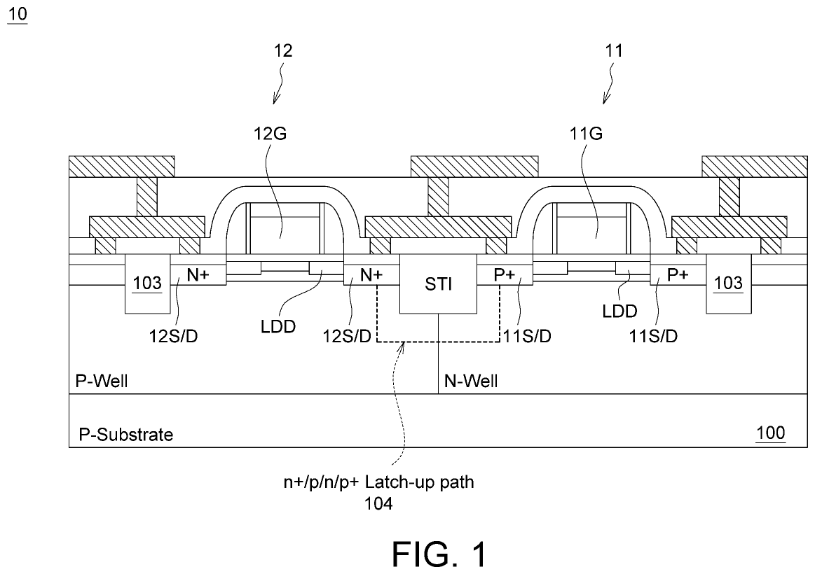

### DETAILED DESCRIPTION OF THE DISCLOSURE

The present disclosure provides a transistor structure and the processing method thereof. The above and other aspects of the disclosure will become better understood by the following detailed description of the preferred but non-limiting embodiment(s). The following description is made with reference to the accompanying drawings:

Several embodiments of the present disclosure are disclosed below with reference to accompanying drawings. However, the structure and contents disclosed in the embodiments are for exemplary and explanatory purposes only, and the scope of protection of the present disclosure is not limited to the embodiments. It should be noted that the present disclosure does not illustrate all possible embodiments, and anyone skilled in the technology field of the disclosure will be able to make suitable modifications or changes based on the specification disclosed below to meet actual needs without breaching the spirit of the disclosure. The present disclosure is applicable to other implementations not disclosed in the specification.

A simple planar NMOS which made in a p-type substrate (or p-well) is used as an example to illustrate the manufacture processes and key attributes of this invention, while similar processes and structures could also be applied to a planar PMOS transistor which is made in an N-well of the p-type substrate.

### Embodiment 1

The flowing description discloses the step for forming a transistor structure 20 according to one embodiment of the present disclosure. In the present embodiment of the present disclosure, the transistor structure 20 may include a planar CMOS device which includes a PMOS transistor 21 and a NMOS transistor 22. The forming of the transistor structure 20 includes steps as follows:
Step S21: providing a semiconductor substrate having at least one active region defined on a semiconductor surface of the semiconductor substrate by at least one shallow trench isolation (STI) region;
Step S22: forming an extending dielectric layer above the STI region, wherein the extending dielectric layer includes a vertical portion; and a top surface of the vertical portion is higher than the semiconductor surface of the semiconductor substrate in the active region. The forming of the extending dielectric layer includes sub-steps S221-S223:
   sub-step S221: sequentially depositing a silicon oxide layer, a silicon nitride (SiN) layer and a spin-on-dopant (SOD) layer to cover the semiconductor surface;
   sub-step S222: etching back the SOD layer, such that a top surface of the SOD layer is aligned with a portion of the SiN layer over the at least one active region; and
   sub-step S223: etching portions of the SiN layer and the silicon oxide layer to expose the at least one active region;
Step S23: forming a gate region with an upper conductive portion and a lower conductive portion over the semiconductor surface, wherein a lateral length of the lower conductive portion is greater than that of the upper conductive portion. The forming of the gate region includes sub-steps S231-S235:
   sub-step S231: sequentially forming a gate dielectric layer, a gate semiconductor layer, a barrier layer, a metal layer, a SiN cap layer and an oxide cap layer to cover the surface of the semiconductor substrate in the active region;
   sub-step S232: etching the oxide cap layer, the SiN cap layer, the metal layer, the barrier layer and partial the gate semiconductor layer to form the upper conductive portion of the gate region above the surface of the semiconductor substrate in the active region;
   sub-step S233: forming an inner spacer contacting the sidewall of the upper portion of the gate region;
   sub-step S234: forming a lower portion of the gate region on the gate dielectric layer and beneath the upper conductive portion; and
   sub-step S235: forming an outer spacer contacting the sidewall of the lower conductive portion;
Step S24: forming at least one isolation region below the semiconductor surface of the semiconductor substrate in the active region. The forming of the at least one isolation region includes sub-steps S241-S243:
   sub-step S241: forming at least one trench below the semiconductor surface of the semiconductor substrate in the active region;
   sub-step S242: forming a thermal oxide layer on the bottom and the sidewalls of the at least one trench; and
   sub-step S243: filling the at least one trench with a dielectric material; and
Step S25: forming at least one conductive region positioned on the at least one isolation region and being independent from the semiconductor substrate. The forming of the conductive region includes sub-steps S251-S253:
   sub-step S251: forming at least one undercut below the gate region to partially expose the semiconductor substrate;
   sub-step S252: forming at least one first selective growth portion of the at least one conductive region in the at least one undercut; and
   sub-step S253: forming at least one second selective growth portion of the at least one conductive region on the dielectric material of the at least one isolation region.

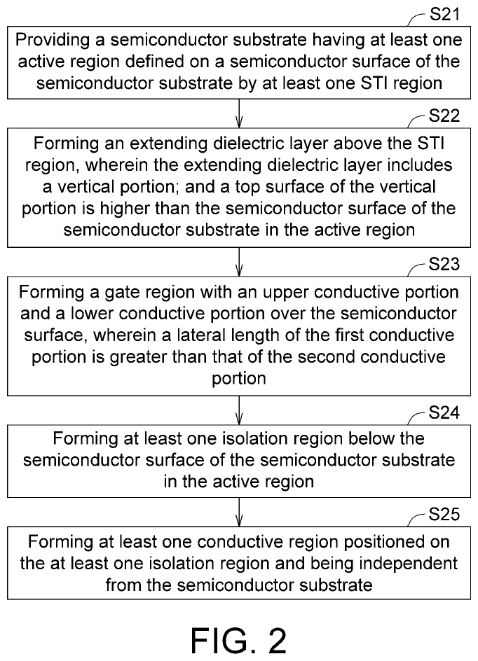

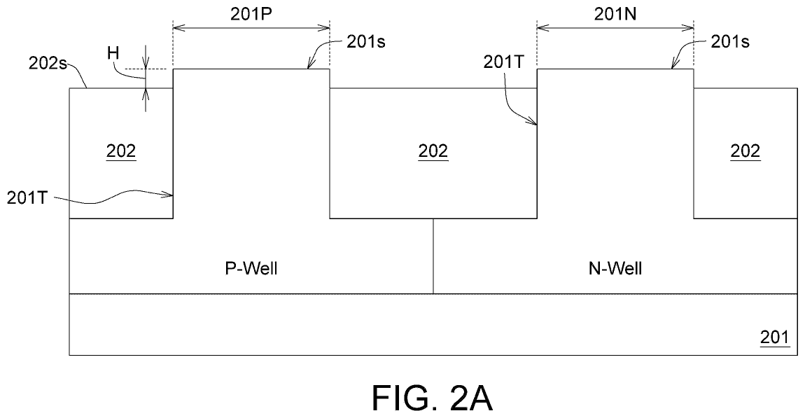

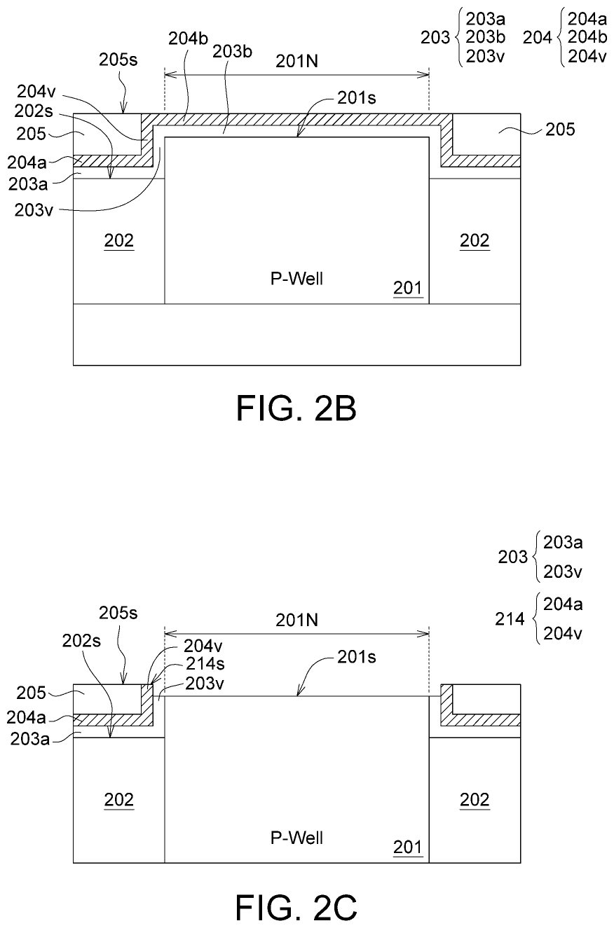

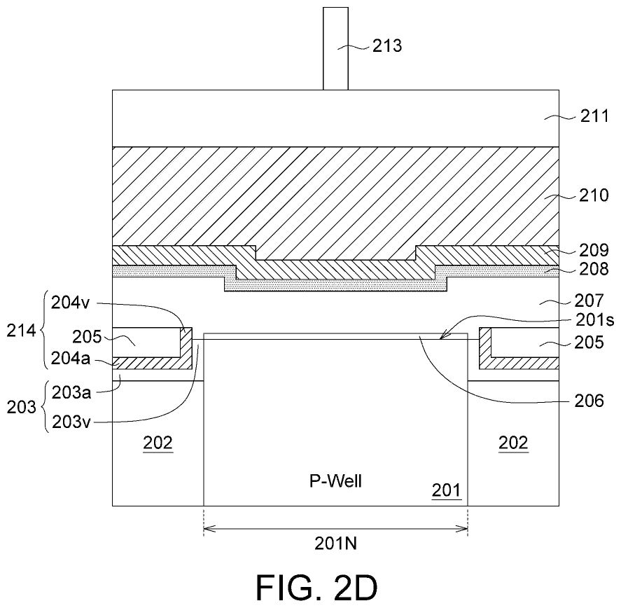

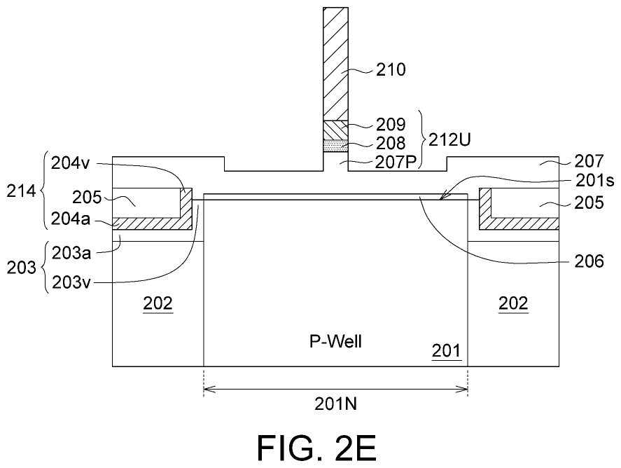

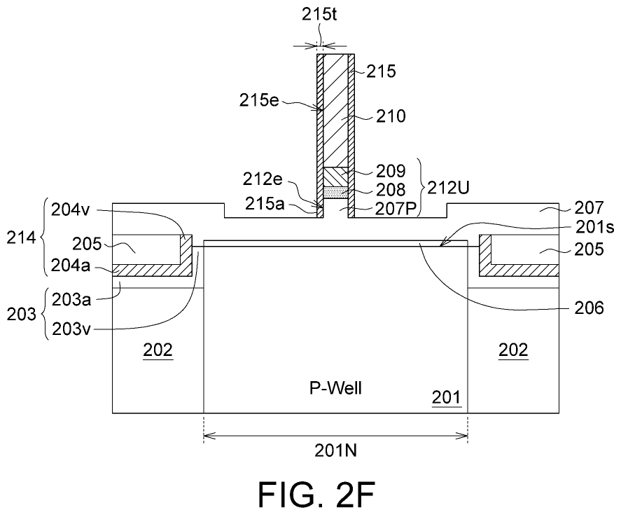

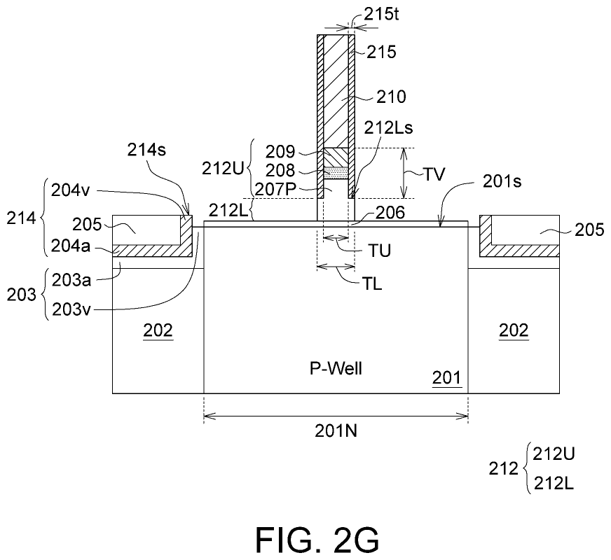

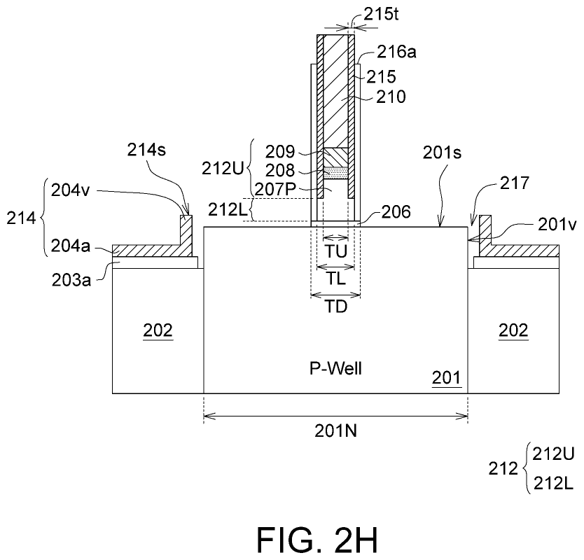

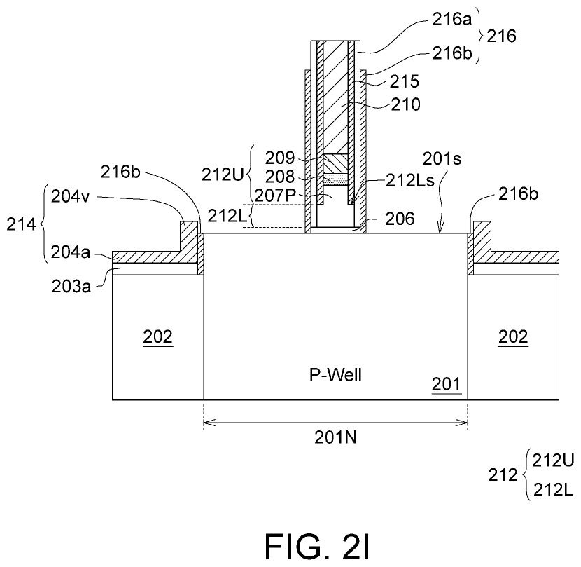

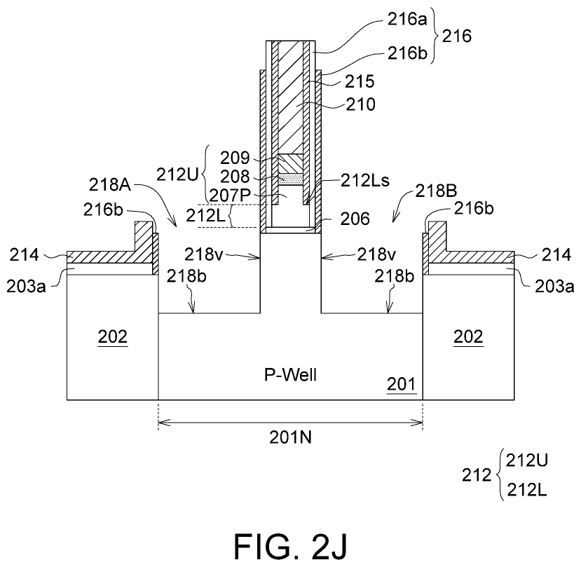

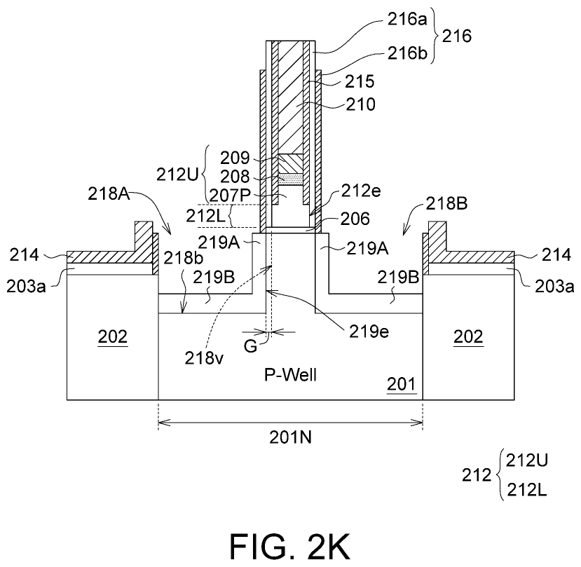

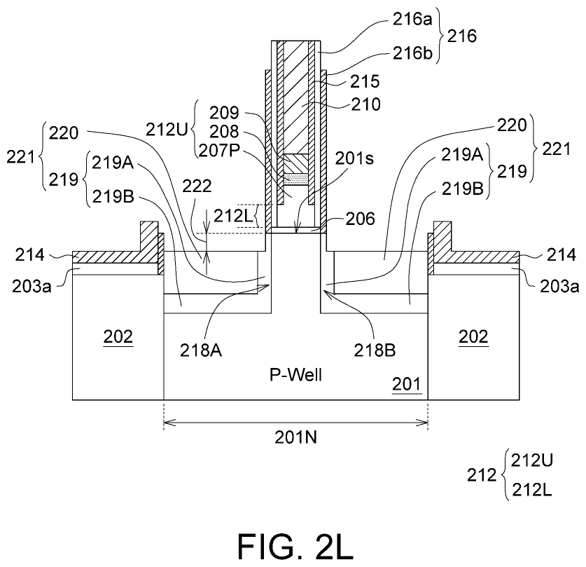

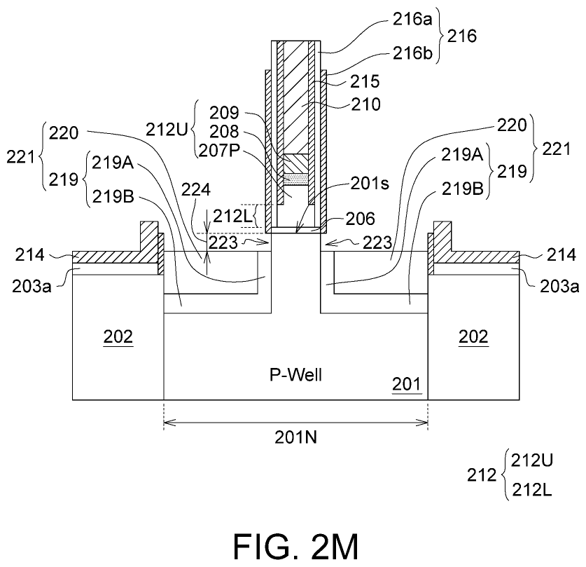

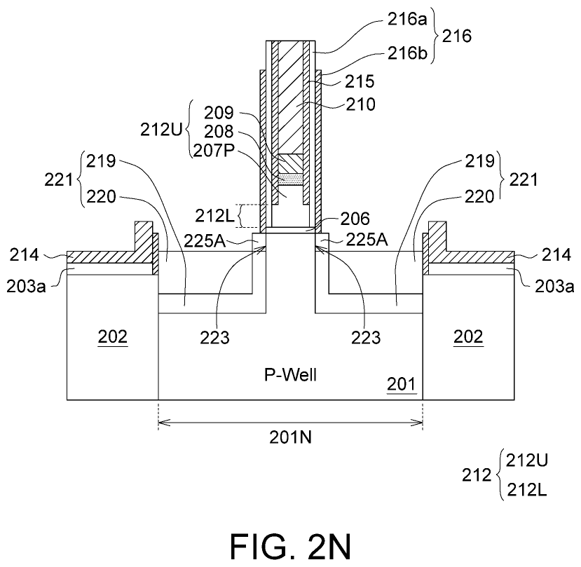

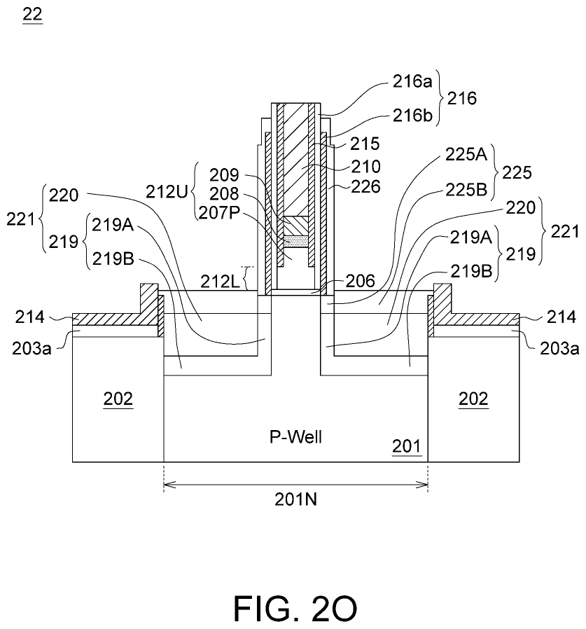

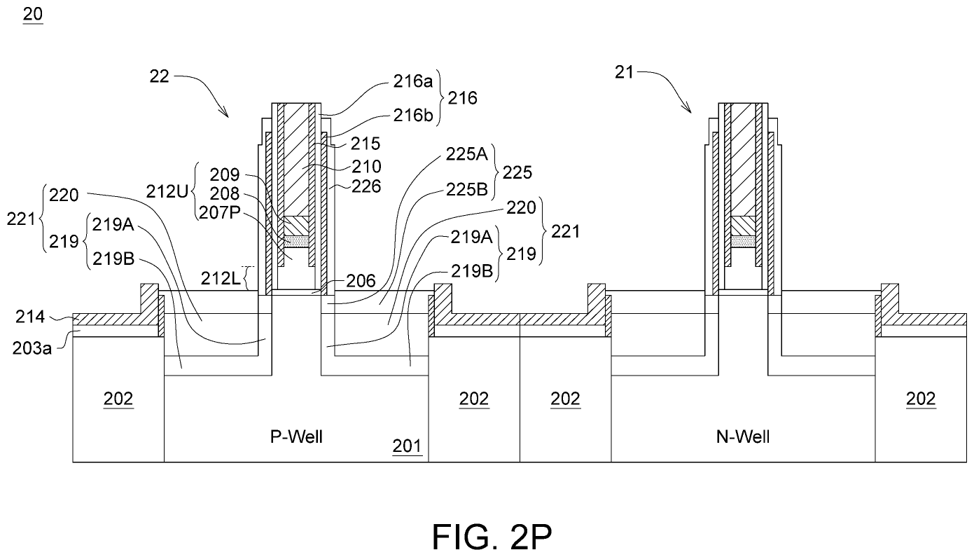

Referring to Step S21: forming a semiconductor substrate having at least one active region defined on a semiconductor surface of the semiconductor substrate by at least one STI region. FIG. 2A is a cross-sectional view illustrating a semiconductor substrate 201 having an active region 201P and an active region 201N defined on a semiconductor surface 201s of the semiconductor substrate 201 by a plurality of STI regions 202 according to one embodiment of the present disclosure.

In the present embodiment, a semiconductor substrate (such as Si substrate) 201 is provided; and an N-well and a P-well are formed in the semiconductor substrate 201, such as, by at least two ion-implantation process carried on the semiconductor surface 201s (i.e., the original silicon surface (OSS) of the Si substrate). The semiconductor substrate 201 is then etched to form a plurality of trenches 201T; and the trenches 201T are filed with dielectric material to form the STI regions 202 surrounding the N-well and P-well respectively. Wherein the N-well surrounded by the STI regions 202 can serve as an active region of the PMOS transistor 21; and the P-well surrounded by the STI regions 202 can serve as an active region of the NMOS transistor 22.

It is noticed that the original silicon surface (OSS) of the Si substrate (the semiconductor surface 201s of the semiconductor substrate 201) is higher than the top surface 202s of the STI 202. For example, in some embodiments of the present disclosure, a distance H between the semiconductor surface 201s (the original silicon surface (OSS) of the Si substrate) and the top surface 202s of the STI 202 measured along a direction perpendicular to the semiconductor surface 201s is about 20 nm to 40 nm (such as about 30 nm).

Referring to Step S22: forming an extending dielectric layer above the STI region, wherein the extending dielectric layer includes a vertical portion and a top surface of the vertical portion is higher than the semiconductor surface of the semiconductor substrate in the active region. The forming of the extending dielectric layer includes sub-steps S221-S223.

Referring to sub-Steps S221 and S222: sequentially depositing a silicon oxide layer 203, a SiN layer 204 and a SOD layer to cover the semiconductor surface, and etching back the SOD layer, such that a top surface of the remaining SOD layer 205 is aligned with an exposed portion of the SiN layer over the at least one active region.

In order to provide a concise and clear description, merely a portion of the planar CMOS device and the processing structures for forming the same are taken as an example and depicted. For example, FIG. 2B is a cross-sectional view illustrating the partial structure (for forming the NMOS transistor 22) after the silicon oxide layer 203, the SiN layer 204 and the SOD layer 205 are sequentially deposited on the semiconductor surface 201s, and the SOD layer 205 is etched back, according to one embodiment of the present disclosure.

In the present embodiment, the silicon oxide layer 203, the SiN layer 204 and the SOD layer 205 are formed by a series deposition processes (e.g., low pressure chemical vapor deposition (LPCVD)) performed sequentially on the semiconductor surface 201s of the semiconductor substrate 201 and the top surface of the STI regions 202. The silicon oxide layer 203 may be a silicon dioxide (SiO₂) conformal with the semiconductor surface 201s of the semiconductor substrate 201 and the top surface of the STI regions 202; the SiN layer 204 is conformal with the silicon oxide layer 203; and the SOD layer 205 is conformal with the SiN layer 204. The silicon oxide layer 203 and the SiN layer 204 both have a thickness less than the distance H between the semiconductor surface 201s and the top surface 202s of the STI 202. In some embodiments, the silicon oxide layer 203 and the SiN layer 204 both have a thickness around 8 nm to 12 nm, such as 10 nm.

In one embodiment, the silicon oxide layer 203 at least include a first oxide portion 203a disposed on the top surface 202s of the STI 202, a second oxide portion 203b disposed on the active regions 201N and a vertical oxide portion 203v disposed on the vertical sidewalls of the P-well. The SiN layer 204 that is conformal with the SiN layer 204 also at least include a first nitride portion 204a disposed on the first oxide portion 203a, a second nitride portion 204b disposed on the second oxide portion 203b and a vertical nitride portion 204v disposed at outer of the vertical oxide portion 203v.

As shown in FIG. 2B, after the SOD layer 205 is etched back, the second nitride portion 204b of the SiN layer 204 over the active regions 201N and 201P is exposed, and the top surface 205s of the SOD layer 205 is aligned with the exposed second nitride portion 204b of the SiN layer 204.

Referring to sub-Step S223: etching portions of the silicon oxide layer and the SiN layer to expose the at least one active region. FIG. 2C is a cross-sectional view illustrating the partial structure (for forming the NMOS transistor 22) after portions of the silicon oxide layer 203 and the SiN layer 204 are etched to expose the active region 201N, according to one embodiment of the present disclosure.

In the present embodiment, an anisotropic etch (such as, a dry etching or a reactive ion etching (RIE)) is performed to remove the second oxide portion 203b of the silicon oxide layer 203 and the second nitride portion 204b of the SiN layer 204 that are not covered by the SOD layer 205 to reveal the semiconductor surface 201s of the semiconductor substrate 201 in the active region 201N.

It is noticed that the vertical oxide portion 203v of the silicon oxide layer 203 and the vertical nitride portion 204v of the SiN layer 204 may extend above the semiconductor surface 201s of the semiconductor substrate 201 (OSS) and surrounds the active region 201N (as shown in FIG. 2C). Wherein, the remained SiN layer 204 including the first nitride portion 204a and the vertical nitride portion 204v could be named as an extending dielectric layer 214; and the top surface 214s of the vertical nitride portion 204v is higher than the semiconductor surface 201s of the semiconductor substrate 201 (OSS). The top surface of the vertical oxide portion 203v of the silicon oxide layer 203 could be substantially aligned with the semiconductor surface 201s of the semiconductor substrate 201 (OSS).

Referring to Step S23: forming a gate region with an upper conductive portion and a lower conductive portion (such as, an upper portion) over the semiconductor surface, wherein a lateral length of the first conductive portion is greater than that of the second conductive portion. The forming of the gate region includes sub-steps S231-S233:

Referring to sub-step S231: sequentially forming a gate dielectric layer, a gate semiconductor layer, a barrier layer, a metal layer, a SiN cap layer and an oxide cap layer to cover the of the active region. FIG. 2D is a cross-sectional view illustrating the partial structure (for forming the NMOS transistor 22) after the gate dielectric layer 206, the gate semiconductor layer 207, the barrier layer 208, and the metal layer 209, the SiN cap layer 210 and the oxide cap layer 211 are formed to cover the semiconductor surface 201s of the semiconductor substrate 201 in the active region 201N, according to one embodiment of the present disclosure.

In some embodiment of the present disclosure, the forming of the gate dielectric layer 206 includes steps as follows: A gate dielectric material layer (such as an oxide layer or a High-K dielectric layer) is formed to cover the semiconductor surface 201s of the semiconductor substrate 201 in the active region 201N. In one embodiment, the dielectric material layer will be formed on semiconductor surface 201s of the semiconductor substrate 201 in the active region 201N.

Subsequently, a series deposition processes (e.g., low pressure chemical vapor deposition (LPCVD)) are performed to sequentially deposit the gate semiconductor layer 207, the barrier layer 208, and the metal layer 209, the SiN cap layer 210 and the oxide cap layer 211 covering the semiconductor surface 201s of the semiconductor substrate 201 in the active region 201N and the extending dielectric layer 214. In the present embodiment, the gate semiconductor layer 207 is a gate poly-silicon layer; the barrier layer 208 is a TiN/Ti composite layer; the metal layer 209 is a tungsten (W)/WSi layer; and the oxide cap layer 211 is a SiO₂ layer.

Referring to sub-step S232: etching the oxide cap layer, the SiN cap layer, the metal layer, the barrier layer and the gate semiconductor layer to form the upper conductive portion of the gate region on the surface of the semiconductor substrate 201 in the active region. FIG. 2E is a cross-sectional view illustrating the partial structure (for forming the NMOS transistor 22) after the upper conductive portion 212U of the gate region 212 is formed on the semiconductor surface 201s of the semiconductor substrate 201 in the active region 201N, according to one embodiment of the present disclosure.

In the present embodiment, the forming of the upper conductive portion 212U of the gate region 212 includes steps as follows: A patterned photoresist layer 213 is formed on the oxide cap layer 211 (as shown in FIG. 2 D); and then the oxide cap layer 211, the SiN layer 210 and the metal layer 209 are patterned by an etching process. After the oxide cap layer 211 is removed, another etching process is performed to remove portions of the barrier layer 208 and the gate semiconductor layer 207 using the remaining portions of the SiN layer 210 as a mask, so as to form a semiconductor (e.g., poly-silicon) pillar 207P beneath the remaining portions of the SiN layer 210, the metal layer 209 and the barrier layer 208. Wherein the semiconductor pillar 207P, the remaining portions of the metal layer 209 and the barrier layer 208 can be combined to refer to as the upper conductive portion 212U of the gate region 212 (as shown in FIG. 2 E).

Referring to sub-step S233: forming an inner spacer contacting the sidewall of the upper conductive portion. FIG. 2F is a cross-sectional view illustrating the partial structure (for forming the NMOS transistor 22) after the inner spacer 215 contacting the sidewalls of the upper conductive portion 212U is formed, according to one embodiment of the present disclosure.

In the present embodiment, the forming of the inner spacer 215 includes steps as follows: A dielectric layer (such as, a SiN layer) is formed to cover the upper conductive portion 212U of the gate region 212 and the remaining portion of the SiN layer 210; and the dielectric layer is then etched to remain the portions thereof covering the remaining portion of the SiN layer 210 and sidewalls of the upper conductive portion 212U to serve as the inner spacer 215. In some embodiments of the present disclosure, an edge 212e of the upper conductive portion 212U is aligned or substantially aligned with an inner edge 215e of the inner spacer 215. The lateral thickness 215t of the inner spacer 215 is about 4 nm to 8 nm, such as 5 nm.

Referring to sub-step S234: forming a lower conductive portion of the gate region on the gate dielectric layer and beneath the upper conductive portion (such as, etch down the gate polysilicon layer 207 outside the inner SiN spacer 215). FIG. 2G is a cross-sectional view illustrating the partial structure (for forming the NMOS transistor 22) after the lower conductive portion 212L of the gate region 212 is formed on the gate dielectric layer 206 and beneath the upper conductive portion 212U, according to one embodiment of the present of disclosure.

In some embodiments of the present disclosure, the lower conductive portion 212L is disposed over the semiconductor surface 201s of the semiconductor substrate 201 in the active region 201N and the upper conductive portion 212U is disposed over the lower conductive portion 212L; and the upper conductive portion 212U includes a metal containing material, and the lower conductive portion 212L is made of a first semiconductor material which is different from the metal containing material.

In the present embodiment, the lower conductive portion 212L can be formed by performing an etching process to remove the portions of the gate semiconductor layer 207 not covered by the remaining portion of the SiN layer 210 and the inner spacer 215. Such that the remaining portion of the gate semiconductor layer 207 positioned underneath the lower conductive portion 212L and the inner spacer 215 can serve as the lower conductive portion 212L. Now the gate region 212 includes the lower conductive portion 212L (made of poly silicon) and the upper conductive portion 212U including the semiconductor pillar 207P (made of poly silicon), the remaining portions of the metal layer ((W)/WSi layer) 209 and the barrier layer 208 (TiN/Ti composite layer).

As shown in FIG. 2G, the gate region 212 just likes a “top-hat” with the wider lower conductive portion 212L and the narrower upper conductive portion 212U. Wherein the lower conductive portion 212L is disposed over the semiconductor surface 201s of the semiconductor substrate 201 in the active region 201N, and the bottom of the lower conductive portion 212L contacts the gate dialectic layer 206. The upper conductive portion 212U is positioned on (connected to) a top surface 212Ls of the lower conductive portion 212L; and the lateral length TL of the lower conductive portion 212L is greater than the lateral length TU of the upper conductive portion 212U. In some embodiments of the present disclosure, the upper conductive portion 212U of the gate region 212 has a vertical thickness TV about 10 nm to 15 nm.

Referring to sub-step S235: forming an outer spacer contacting the sidewall of the lower conductive portion. In the present embodiment, the forming of the outer spacer 216 includes steps as follows: A dielectric layer 216a made of a dielectric material (such as, SiO₂) other than that for consisting the inner spacer 215 is formed to at least blanket over the inner spacer 215, the sidewalls of the lower conductive portion 212L, and the gate dielectric layer 206. The dielectric layer 216a is then etched to remain the portion thereof covering the sidewalls of the lower conductive portion 212L and the inner spacer 215, so as to partially expose the semiconductor surface 201s of the semiconductor substrate 201 in the active region 201N.

It is noticed that, in some embodiments of the present disclosure, the portion of the gate dielectric layer 206 not covered by the remaining portions of the SiN layer 210, the inner spacer 215 and the remaining portion of the dielectric layer 216a can be removed simultaneously by the etching process. Thus, the lateral length TD of the remaining portion of the gate dielectric layer 206 is also greater than the lateral length TU of the upper conductive portion 212U, and also greater than the lateral length TL of the lower conductive portion 212L. Moreover, the remaining portions of the SOD layer 205 and the vertical oxide portion 203v of the silicon oxide layer 203 could also be removed by the same etching process. Such that a gap 217 can be formed between the vertical nitride portion 204v of the extending dielectric layer 214 and the vertical sidewall 201v of the semiconductor substrate 201 (as shown in FIG. 2H)

Subsequently, another dielectric layer 216b made of a dielectric material (such as, SiN) other than that for consisting the dielectric layers 216a is formed to blanket over the top surface of the SiN layer 210, the inner spacer 215, the dielectric layer 216a, the exposed semiconductor surface 201s of the semiconductor substrate 201 in the active region 201N and the extending dielectric layer 214; and such dielectric material could fill the gap 217 as well. The dielectric layer 216b is then etched to partially expose the semiconductor surface 201s of the semiconductor substrate 201 in the active region 201N. The reaming portions of these two dielectric layers 216a and 216b that are disposed to cover the inner spacer 215 and gate region 212 can be combed to form the outer spacer 216.

In some embodiments of the present disclosure, since the extending dielectric layer 214 and the dielectric layer 216b are made of the same material (such as, SiN), the portions of the dielectric layer 216b remained on the extending dielectric layer 214 may enlarge the thickness of the extending dielectric layer 214. Similarly, the lateral width of the extending dielectric layer 214 may be enlarged by the remaining portions of the dielectric layer 216b disposed in the gap 217.

FIG. 2I is a cross-sectional view illustrating the partial structure (for forming the NMOS transistor 22) after the outer spacer 216 is formed, and also fills the gap 217 between active region 201N and STI regions 202 to enhance the confine wall (including the vertical nitride portion 204v and the portion of the first oxide portion 203a exposed from the gap 217), according to one embodiment of the present disclosure. Wherein, the later width of these two dielectric layers 216a and 216b are around 5 nm, respectively. The inner spacer 215 contacts sidewalls of the upper conductive portion 212U rather than the lower conductive portion 212L; and the dielectric layer 216a of the outer spacer 216 contacts the lower conductive portion 212L; the dielectric layer 216b of the outer spacer 216 contacts the dielectric layer 216a.

Referring to Step S24: forming at least one isolation region below the semiconductor surface of the semiconductor substrate in the active region. The forming of the at least one isolation region includes sub-steps S241-S243.

Referring to sub-step S241: forming at least one trench below the semiconductor surface of the semiconductor substrate in the active region. FIG. 2J is a cross-sectional view illustrating the partial structure (for forming the NMOS transistor 22) after the trenches 218A and 218B are formed in the semiconductor substrate 201 below the semiconductor surface 201s of the semiconductor substrate 201 in the active region 201, according to one embodiment of the present disclosure. In the present embodiment, the trenches 218A and 218B are formed by performing an anisotropic etch (such as, a dry etching or a RIE) to remove a portion of the semiconductor substrate 201 in the active region 201N.

Wherein, each of the trenches 218A and 218B has a depth measured from bottoms 218b and a vertical sidewall 218v with predetermined crystal oriented silicon (such as (110)) right under the outer spacer 216. In some embodiments, the depth of the trenches 218A and 218B may be from 100 nm to 120 nm (such as, 110 nm), and one of the sidewalls of the trenches 218A and 218B may be defined by the STI 202.

Referring to sub-step S242: forming a thermal oxide layer on the bottom and the sidewalls of the at least one trench. FIG. 2K is a cross-sectional view illustrating the partial structure (for forming the NMOS transistor 22) after the thermal oxide layer 219 is formed on the bottoms and the sidewalls of the trenches 218A and 218B, according to one embodiment of the present disclosure.

In the present embodiment, a thermal oxidation process is performed to grow the thermal oxide layer 219 (such as, a silicon oxide layer) on the bottoms and the sidewalls of the trenches 218A and 2188. As shown in FIG. 2K, the portion of the thermal oxide layer 219 formed in each of the trenches 218A and 218B has a thermal oxide vertical portion 219A penetrating in to the semiconductor substrate 201 from the exposed vertical sidewall 218v (with (110)-oriented silicon) of the trench 218A or 218B, and a thermal oxide bottom portion 219B penetrating in to the semiconductor substrate 201 from the bottom 218b of the trench 218A or 2188.

In one embodiment, the thickness of the thermal oxide vertical portion 219A and the thermal oxide bottom portion 219B could be around 20 nm. However, it is important to design this thermal oxidation process such that the thickness of the thermal oxide vertical portion 219A can be very accurately controlled under both precisely controlled thermal oxidation temperature, timing and growth rate. The thermal oxidation over a well-defined silicon surface result in that 40% of the thickness of the thermal oxide vertical portion 219A extends into the transistor body (semiconductor substrate 201) from the exposed vertical sidewall 218v (with (110)-oriented silicon), and that the remaining 60% of the thickness of the thermal oxide vertical portion 219A counted as an addition part extends into the trenches 218A or 218B from the vertical sidewall 218v.

Since the thickness of the thermal oxide vertical portion 219A is very accurately controlled based on the thermal oxidation process, the edge of the thermal oxide vertical portion 219A could be controlled, such as the gap G between the edge 219e of the thermal oxide vertical portion 219A and the edge 212e of the lower conductive portion 212L of the gate region 212 is around 2 nm to 4 nm or less (as shown in FIG. 2K), or the gap G could be 0.

Referring to sub-step S243: filling the at least one trench with a dielectric material to form the at least one isolation region. FIG. 2L is a cross-sectional view illustrating the partial structure (for forming the NMOS transistor 22) after the trenches 218A and 218B are filled with the dielectric material 220 to form a plurality of isolation regions 221, according to one embodiment of the present disclosure.

In the present embodiment, the dielectric material 220, such as SOD or Nitride, is deposited over the gate region 212, the SiN cap layer 210, the inner spacer 215, the outer space 216, the extending dielectric layer 214 and the active region 201 with sufficient thickness to fully fill up both the trenches 218A and 218B. An etching back process is then performed to remove the unnecessary portion of the dielectric material 220 (SOD) to leave only a suitable thickness of the dielectric material 220 (also referred to as filling dielectric regions) inside the trenches 218A and 218B. Wherein the portions of the thermal oxide layer 219 and the remaining dielectric material 220 (SOD) that are disposed in one of the trenches 218A and 218B can be combined to serve as one of the isolation regions 221, which is also referred to as a localized isolation into silicon substrate (LISS). It is noticed that the gap 222 between the semiconductor surface 201s of the semiconductor substrate 201 (OSS) and the top surface of the remaining dielectric material 220 (SOD) is 6 nm to 12 nm, such as 9 nm.

Referring to Step S25: forming at least one conductive region positioned on the at least one isolation region and being independent from the semiconductor substrate. The forming of the conductive region includes sub-steps S251-S253:

Referring to sub-step S251: forming at least one undercut below the gate region to partially expose the semiconductor substrate. FIG. 2M is a cross-sectional view illustrating the partial structure (for forming the NMOS transistor 22) after a plurality of undercuts 223 are formed below the gate region 212 to partially expose the semiconductor substrate 201, according to one embodiment of the present disclosure. In the present embodiment, a well-designed anisotropic etching (such as wet etching) process is performed to remove the portions of the thermal oxide vertical portion 219A within the trenches 218A and 218B, so as to expose portions of the semiconductor substrate 201 each of which has an exposed silicon surface with a uniform (110) crystalline orientation.

It is noted that (as shown in FIG. 2M) each portion of the semiconductor substrate 201 exposed from one of the undercuts 223 has a vertical boundary with a suitable recessed thickness; and the undercuts 223 are just right underneath the outer spacer 216, rather than the gate region 212. Thus, it is guaranteed that the portion of the gate dielectric layer 206 under gate region 212 is unetched and remains it completeness. In one embodiment, the gap 224 between the semiconductor surface 201s of the semiconductor substrate 201 (OSS) and the top of the remaining the thermal oxide vertical portion 219A can be around 17 nm to 19 nm.

Referring to sub-step S252: forming at least one first selective growth portion of the at least one conductive region in the at least one undercut. FIG. 2N is a cross-sectional view illustrating the partial structure (for forming the NMOS transistor 22) after a plurality of first selective growth portions 225A are formed in the undercuts 223, according to one embodiment of the present disclosure.

A selective growth technique (such as, selective epitaxial growth (SEG) or other suitable technology which may be atomic layer deposition (ALD) or selective growth (ALD-SALD)) to grow the first selective growth portions 225A from the silicon surface exposed from the undercuts 223. In the present embodiment, each of the first selective growth portions 225A may have an n-type electricity serving as the LDD regions and can be used as crystalline seeds to form a new well-organized (110) lattice source/drain region of the NMOS transistor 22 across the thermal oxide layer 219. Each of the first selective growth portions 225A has a lateral thickness around 20 nm.

Referring to sub-step S253: forming at least one second selective growth portion of the at least one conductive region. FIG. 2O is a cross-sectional view illustrating the partial structure (for forming the NMOS transistor 22) after a plurality of second selective growth portions 225B are formed on the dielectric material 220 of the isolation regions 221, according to one embodiment of the present disclosure.

In the present embodiment, prior to forming of the second selective growth portion 225B, an optional composite dielectric layer, including a SiN layer and a SiO₂ (or SiCON) layer are sequentially deposited to cover the SiN layer 210, the inner spacer 215 and the outer spacer 216, the isolation regions 221 and the extending dielectric layer 214; then the composite dielectric layer is etched by several etching process to form a composite spacer 226 covering on the outer spacer 216 and the tops of the first selective growth portions 225A (serving as the N-LDD regions). It is noticed that, since the first selective growth portions 225A (serving as the N-LDD regions) are covered by the composite spacer 226, thus an upward growth can be prevented from the first selective growth portions 225A.

Afterward, a further selective growth process is performed to grow N+ doped regions along the vertical walls of the first selective growth portions 225A with (110) orientation, so as to form the second selective growth portion 225B within the trenches 218A and 218B and extending beyond the same. Wherein, the combination of one of the first selective growth portions 225A and one of the second selective growth portions 225B both disposed in the same trench (trench 218A or 218B) may be referred to as the conductive regions 225, and serve as the source region or the drain region of the NMOS transistor 22.

In some embodiments of the present disclosure, the conductive regions 225 are confined by the extending dielectric layer 214. In the present embodiment, as shown in FIG. 2O, the N+ doped regions of the second selective growth portions 225B are laterally grown until to the vertical portion 214v (including the vertical nitride portion 204v and the portion of the dielectric layer 216b that fills the gap 217) of the extending dielectric layer 214 surrounding the active region 201N, In other word, the vertical portion 214v of the extending dielectric layer 214 surrounding the active region 201N serves as a reference or barrier for the selective growth process to grow the second selective growth portion 225B of the conductive regions 225.

Similarly, the planar PMOS transistor 21 can be formed by the same process as described above, simultaneous with the process for forming the planar NMOS transistor 22, or formed independent from the process for forming the planar NMOS transistor 22. After a series steps of down-stream process are performed, the forming of the transistor structure (e.g., the CMOS device) 20 can be implemented (as shown in FIG. 2P).

It is noticed that, in the present invention there are two or more separate steps of lateral selective growth of the source/drain regions (the conductive regions 225), the first one is lateral selective growth of the N-LDD or P-LDD region (e.g., the first selective growth portion 225A), and the second one is lateral selective growth of N+ or P+ doped regions (e.g., the second selective growth portion 225B). The growth temperature of the first step could be different form that of the second step. Moreover, the grown material (such as Si) of the first step could be different from the grown material (such as, SiGe, SiC, W, or other selective grown material) of the second step in order to reduce the resistances of Source/Drain regions or increase the stress force to the initial portions of Source/Drain regions into the channel region to increase mobility.

After this SEG processes for forming the source/drain regions (the conductive regions 225) are completed, there are some novel results achieved:
(1) The new source/drain regions formed by all (110)-oriented crystalline silicon can improve the performance of the source/drain regions, in comparison with that formed by conventional way of growing from two different seeding regions to cause lattice mixtures of (100)-oriented silicon and (110)-oriented silicon;
(2) The well-defined (110) crystalline of the newly grown silicon structures is closely seamless with the effective channel length and perfectly intact, which gives exactly controlled size of transistor width;
(3) The newly grown silicon regions can grow with in-situ doped dopants of either phosphorous/arsenic atoms for NMOS or boron atoms for PMOS. With such an in-situ doping silicon-growth technique the source/drain can be well designed to have LDD regions for controllable lateral distances and then be changed to heavily doped source/drain regions; the LDD regions are covered by a SiO2 layer and a SiN layer (of a composite spacer) to prevent the upward growth of the N-LDD regions during the formation of heavily doped source/drain regions.
(4) Since there is no need to use ion-implantation to form LDD regions so that there is no need to use thermal annealing process to reduce defects. Therefore, as no extra defects are generated once which were induced and hard to totally eliminate even by annealing process any unexpected leakage current sources should be significantly minimized;
(5) Only (110)-oriented lattice structure must be handled along the channel-to-Source/Drain regions in contrast to that the conventional way of forming such conduction channels must handle a mixture of (110)-oriented and (100)-oriented lattice structures. So it is expected that newly grown silicon regions outgrowth from both transistors body and channel region with precisely controllable SEG should create better high quality/high-performance source/drain-to-channel conduction mechanism. The sub-threshold leakage should be reduced. The channel conduction performance should be enhanced since the conduction mechanism from channel-through LDD-to heavily-doped source/drain regions can thus have a holistic design even including some stressed-channel-mobility-enhancement technique by inserting foreign atoms/ions uniformly into source/drain regions could have synergistic effects for enhancing on-conduction performance;
(6) Another big advantage is that since the vertical boundary between the edge of gate region and the edge of the newly grown silicon region can be well defined based on thermal-oxidation controllability, the GIDL effect should be reduced in contrast to the conventional way of using LDD implantation to serve as the alignment of gate-edge to LDD, Since the thickness of the vertical portion of the thermal oxide layer is very accurately controlled based on the thermal oxidation process, the edge of the vertical thermal oxide layer could be controlled, and the edge of the vertical portion of the thermal oxide layer is just right underneath the outer spacer, rather than underneath the gate region. Thus, it is guaranteed that the gate dielectric layer (such as gate oxide layer) is unetched and remains it completeness during the etching of the composite layer for forming the composite spacer. In one embodiment, the gap between the edge of the vertical portion of the thermal oxide layer and the edge of the lower conductive portion of the gate region is around 2 nm (as shown in FIG. 2K). Thus, the length of the gate region is shorter than the lateral distance between the vertical portion of the thermal oxide layer in the source trench and the other vertical portion of the thermal oxide layer in the drain trench.
(7) Since most the Source/Drain areas are isolated by insulation materials including the bottom structure of LISS, the junction leakage possibility can only happen to very small areas of the newly grown silicon region to channel regions and thus be significantly reduced.
(8) The SiN layer (e.g., the extending dielectric layer) surrounding the active region will be used as a reference or barrier for selective growth of source/drain regions, thus the selective growth of source/drain regions will not extend over the SiN layer (e.g., the extending dielectric layer) to contact with other selectively grown source/drain regions.

As such a newly grown silicon region is formed as described and shown in the aforementioned text, the remaining transistor formation steps can be continued to fill the entire source/drain regions with well-designed doping concentration profiles as desired. Another way of complete the active portions of source/drain regions is that, some tungsten (or other suitable metal materials) plugs can be formed in a horizontal connection to the silicon portion of source/drain for completion of the entire source/drain regions. The active channel current flowing to future metal interconnection such as a metal-1 layer is gone through LDD regions and heavily-doped conductive silicon source/drain regions to the tungsten (or other metal materials) plugs which are directly connected to Metal-1 by some good Metal-to-Metal Ohmic contact with much lower resistance than the traditional Silicon-to-Metal contact.

Of course, the present invention not only could be implemented in the planar MOSFET, but also be implemented in non-planar MOSFET, such as FinFET, Tri-gate, GAA (Gate-All-Around) transistors.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A transistor structure comprising
a semiconductor substrate with an active region and with a semiconductor surface;
a gate region with a first gate conductive portion over the semiconductor surface of the semiconductor substrate and a second gate conductive portion over the first conductive portion;
a spacer covering a sidewall of the gate region;
a trench formed below the semiconductor surface of the semiconductor substrate;
an isolation region in the trench; and
a conductive region positioned on the isolation region and disposed in the trench;
wherein a lateral length of the first gate conductive portion is greater than that of the second gate conductive portion.

2. The transistor structure according to claim 1, wherein the isolation region includes a vertical layer and a bottom layer; an edge of the vertical layer is underneath the spacer; and a gap between the edge of the vertical layer and an edge of the first gate conductive portion of the gate region is less than 3 nm.

3. The transistor structure according to claim 1, wherein the conductive region is independent from the semiconductor substrate.

4. The transistor structure according to claim 3, wherein the transistor structure is a planar NMOS transistor, the conductive region comprises an N type lightly-doped drain (LDD) region and an N type heavily doped region contacting with the N type LDD region.

5. The transistor structure according to claim 4, wherein a top surface of the N type LDD region is substantially covered by the spacer.

6. The-transistor structure according to claim 5, wherein the isolation region further comprises a filling dielectric region on the bottom layer, and a top surface of the vertical layer is aligned or substantially aligned with that of the filling dielectric region.

7. The-transistor structure according to claim 6, wherein the vertical layer and the bottom layer of the isolation region are made of oxide, and the filling dielectric region is made of a spin-on-dopant (SOD) layer.

8. The transistor structure according to claim 6, wherein the N type LDD region is on the vertical layer and the N type heavily doped region is on the filling dielectric region.

9. The transistor structure according to claim 8, wherein a vertical thickness of the N type LDD region is less than 20 nm, and a lateral width of the N type LDD region is between 10-30 nm.

10. The transistor structure according to claim 1, further comprising a shallow trench isolation (STI) region below the semiconductor surface of the semiconductor substrate and an extending dielectric layer above the STI region, wherein the extending dielectric layer includes a vertical portion, and a top surface of the vertical portion is higher than the semiconductor surface of the semiconductor substrate.

11. The transistor structure according to claim 10, wherein the conductive region is confined by the vertical portion of the extending dielectric layer.

12. A transistor structure comprising:
a semiconductor substrate with an active region and with a semiconductor surface;
a first trench and a second trench, both formed below the semiconductor surface;
a first isolation region in the first trench;
a second isolation region in the second trench;
a gate region with a first gate conductive portion over the semiconductor surface of the semiconductor substrate and a second gate conductive portion over the first gate conductive portion;
a channel region being under the gate region;
a drain region with a first doping type on the first isolation region; and
a source region with the first doping type on the second isolation region;
wherein a lateral length of the first gate conductive portion is different from that of the second gate conductive portion, and a distance between an edge of the first isolation region and an edge of the second isolation region is greater than the lateral length of the first gate conductive portion.

13. The transistor structure according to claim 12, wherein the distance between the edge of the first isolation region and the edge of the second isolation region is greater than the length of the lateral length of the first gate conductive portion around 2-6 nm.

14. The transistor structure according to claim 12, further comprising a STI region below the semiconductor surface of the semiconductor substrate and an extending dielectric layer above the STI region, wherein the extending dielectric layer includes a vertical portion surrounding the active region, and a top surface of the vertical portion is higher than the semiconductor surface of the semiconductor substrate.

15. The transistor structure according to claim 14, wherein the drain region and the source region are confined by the vertical portion of the extending dielectric layer.

16. A transistor structure comprising
a semiconductor substrate, with an active region and with a semiconductor surface; and
a gate region with a first gate conductive portion over the semiconductor surface of the semiconductor substrate and a second gate conductive portioned over the first gate conductive portion;
wherein a lateral length of the first gate conductive portion is greater than that of the second gate conductive portion.

17. The transistor structure according to claim 16, further comprising a first spacer and a second spacer, wherein the second spacer contacts sidewalls of the second gate conductive portion rather than the first gate conductive portion, and the first spacer contacts sidewalls of the first gate conductive portion.

18. The transistor structure according to claim 17, wherein an edge of the second gate conductive portion is aligned or substantially aligned with an edge of the second spacer.

19. The transistor structure according to claim 17, wherein the second gate conductive portion includes a metal containing material, and the first gate conductive portion is made of a first semiconductor material which is different from the metal containing material.

20. The transistor structure according to claim 16, further comprising a gate dielectric layer under the first gate conductive portion, and a lateral length of the gate dielectric layer is greater than that of the second gate conductive portion.

21. The transistor structure according to claim 16, wherein a length of the gate region is immune from a gate line edge roughness.

22. The transistor structure according to claim 16, wherein a vertical thickness of the first gate conductive portion is 10 nm to 15 nm.
